(19) United States
(12) Patent Application Publication
(10) Pub. No.: US 2025/0132247 A1
(43) Pub. Date: Apr. 24, 2025

(54) INTERCONNECTION STRUCTURE

(71) Applicant: TAIWAN SEMICONDUCTOR MANUFACTURING COMPANY, LTD., Hsinchu (TW)

(72) Inventors: Chi-Lin TENG, Hsinchu (TW); Gary LIU, Hsinchu (TW); Ting-Ya LO, Hsinchu (TW); Yen-Ju WU, Hsinchu (TW); Shao-Kuan LEE, Hsinchu (TW); Kuang-Wei YANG, Hsinchu (TW); Hsin-Yen HUANG, Hsinchu (TW); Hsiao-Kang CHANG, Hsinchu (TW)

(73) Assignee: TAIWAN SEMICONDUCTOR MANUFACTURING COMPANY, LTD., Hsinchu (TW)

(21) Appl. No.: 18/493,293

(22) Filed: Oct. 24, 2023

(51) Int. Cl. H01L 23/522; H01L 21/768; H01L 23/532

(52) U.S. Cl. CPC H01L 23/5226; H01L 21/76816; H01L 21/76832; H01L 21/7684; H01L 21/76877; H01L 23/53295

(57) ABSTRACT

An interconnection structure is provided to include a substrate, a first metal trench, a boron nitride dielectric, a second metal trench, and a metal via. The substrate is formed with a first metal trench. The boron nitride dielectric is disposed over the substrate. The second metal trench is formed in the boron nitride dielectric. The metal via is disposed to interconnect the first metal trench and the second metal trench.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics play a role in IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating steps of a method for fabricating an interconnection structure in accordance with a first embodiment.

FIGS. 2 through 5 are sectional views illustrating intermediate stages of the method for fabricating the interconnection structure in accordance with the first embodiment.

FIG. 6 is a flow chart illustrating steps of a method for fabricating an interconnection structure in accordance with a second embodiment.

FIGS. 7 through 20 are sectional views illustrating intermediate stages of the method for fabricating the interconnection structure in accordance with the second embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

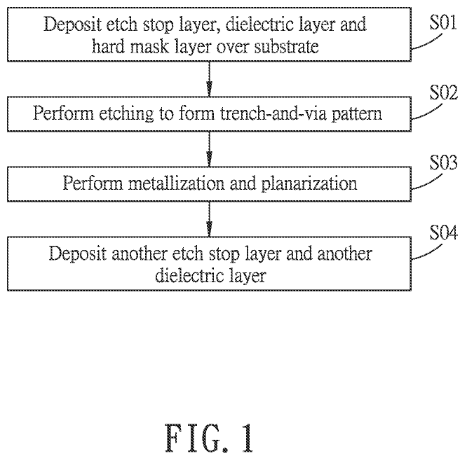

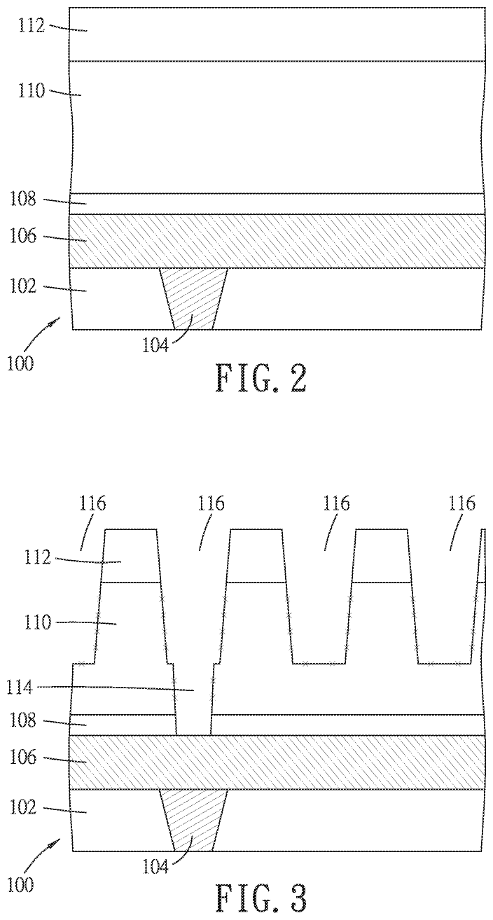

FIG. 1 is a flow chart that cooperates with FIGS. 2 through 5 to illustrate steps of a method for fabricating an interconnection structure in accordance with a first embodiment, where FIGS. 2 through 5 exemplarily depict a dual damascene process. Referring to FIG. 2, a substrate 100 is provided. The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon substrate; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GaInAs, GaInP, GaInAsP or other suitable materials.

In some embodiments, the substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 100 may include lateral isolation features (e.g., shallow trench isolation (STI)) configured to separate various functional elements formed on the substrate 100 and/or various functional elements formed in the substrate 100.

In the illustrative embodiment, the substrate 100 includes a first dielectric layer 102, a first metal via 104 that is formed in the first dielectric layer 102 and that extends vertically relative to a top surface of the substrate 100, and a first metal trench (or metal line) 106 that is formed over and connected to the first metal via 104 and that extends horizontally relative to the top surface of the substrate 100. It is noted that the first metal trench 106 is formed in and surrounded by the first dielectric layer 102, although it is not shown from the perspective of FIG. 2. In accordance with some embodiments, the first dielectric layer 102 may be composed of, for example, Si, C, O, H, low-k materials, other suitable elements and/or materials, or any combination thereof, and may be formed using, for example, chemical vapor deposition (CVD), atomic layer deposition (ALD), other suitable techniques, or any combination thereof. In accordance with some embodiments, the first dielectric layer 102 may have a thickness in a range from about 100 angstroms to about 2000 angstroms. In accordance with some embodiments, the first metal via 104 and the first metal trench 106 may include, for example, Cu, Co, Ru, Mo, Cr, W, Mn, Rh, Ir, Ni, Pd, Pt, Ag, Au, Al, alloys of these metal elements, other suitable materials, or any combination thereof, and may be formed using, for example, physical vapor deposition (PVD), CVD, ALD, other suitable techniques, or any combination thereof. The first metal via 104 and the first metal trench 106 may include either the same material(s) or different materials. In accordance with some embodiments, each of the first metal via 104 and the first metal trench 106 may have a thickness in a range from about 50 angstroms to about 500 angstroms.

Referring to FIGS. 1 and 2, a first etch stop layer 108, a second dielectric layer 110 and a hard mask layer 112 are deposited over the substrate 100 in the given order (step S01). The first etch stop layer 108 may be composed of, for example, Al-based materials (e.g., AlNₓ, AlON, AlOₓ, etc.), Si-based materials (e.g., SiCO, SiCN, SiN, SiCON, etc.), other suitable materials, or any combination thereof, and may be formed using, for example, PVD, CVD, ALD, other suitable techniques, or any combination thereof. In accordance with some embodiments, the first etch stop layer 108 may be of either a single-layer structure or a multilayer structure, and may have a thickness in a range from about 2 angstroms to about 200 angstroms. In accordance with some embodiments, the second dielectric layer 110 may be composed of, for example, Si, C, O, H, low-k materials, other suitable elements and/or materials, or any combination thereof, and may be formed using, for example, CVD, ALD, other suitable techniques, or any combination thereof. In accordance with some embodiments, the second dielectric layer 110 may have a thickness in a range from about 100 angstroms to about 2000 angstroms. In accordance with some embodiments, the hard mask layer 112 may be of either a single-layer structure or a multilayer structure, where each layer may be composed of, for example, Si, W, Ti, Be, Hf, Zr, O, N, C, other suitable elements, or any combination thereof, and may be formed using, for example, CVD, ALD, spin-on deposition, other suitable techniques, or any combination thereof. In accordance with some embodiments, the hard mask layer 112 may have a thickness in a range from about 100 angstroms to about 500 angstroms.

Referring to FIGS. 1 and 3, the hard mask layer 112, the second dielectric layer 110 and the first etch stop layer 108 are etched to form a trench-and-via pattern (step S02), where the hard mask layer 112 serves as an etching mask during the etching of the second dielectric layer 110. In the illustrative embodiment, the trench-and-via pattern exemplarily includes multiple trench recesses 116 and a via hole 114, but this disclosure is not limited in this respect. In accordance with some embodiments, the hard mask layer 112 may be patterned using a lithography process, and may be etched using, for example, wet etching, dry etching, other suitable techniques, or any combination thereof. In accordance with some embodiments, the second dielectric layer 110 and the first etch stop layer 108 may be etched using, for example, anisotropic etching, such as reactive-ion etching (RIE), ion beam etching (IBE), other suitable techniques, or any combination thereof, with the patterned hard mask layer 112 serving as an etching mask. Each of the via hole 114 and the trench recesses 116 may have a width that gradually increases from bottom to top due to the nature of etching, and thus may have a top width that is greater than its bottom width.

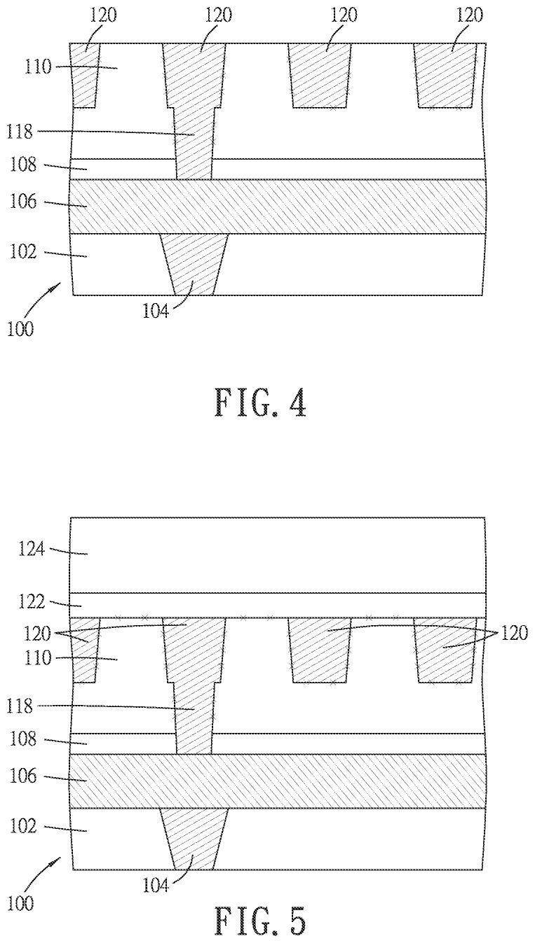

Referring to FIGS. 1 and 4, a metallization process is performed to deposit one or more metal layers to fill the via hole 114 and the trench recesses 116 (see FIG. 3), followed by a planarization process (e.g., a chemical-mechanical planarization (CMP) process), thereby forming a second metal via 118 that corresponds to the via hole 114 as shown in FIG. 3, and multiple second metal trenches 120 that respectively correspond to the trench recesses 116 as shown in FIG. 3 (step S03). In accordance with some embodiments, the second metal via 118 and the second metal trenches 120 may include, for example, Cu, Co, Ru, Mo, Cr, W, Mn, Rh, Ir, Ni, Pd, Pt, Ag, Au, Al, alloys of these metal elements, other suitable materials, or any combination thereof, and may be formed using, for example, PVD, CVD, ALD, other suitable materials, or any combination thereof. The second metal via 118 and the second metal trenches 120 may include either the same material(s) or different materials. In accordance with some embodiments, each of the second metal via 118 and the second metal trenches 120 may have a thickness in a range from about 50 angstroms to about 500 angstroms. Following the shapes of the via hole 114 and the trench recesses 116, each of the second metal via 118 and the second metal trenches 120 may have a width that gradually increases from bottom to top, and thus may have a top width that is greater than its bottom width.

Referring to FIGS. 1 and 5, a second etch stop layer 122 and a third dielectric layer 124 are deposited in the given order over the second dielectric layer 110 and the second metal trenches 120 (step S04). Before the deposition of the second etch stop layer 122, a pretreatment process may be applied in order to remove metal oxides that may have been formed on top of the second metal trenches 120 during a time gap between the formation of the second metal trenches 120 and the deposition of the second etch stop layer 122, and the pretreatment process may use, for example, NH₃ plasma, H₂ plasma, other suitable treatments, or any combination thereof. The second etch stop layer 122 may be composed of, for example, Al-based materials (e.g., AlNₓ, AlON, AlOₓ, etc.), Si-based materials (e.g., SiCO, SiCN, SiN, SiCON, etc.), other suitable materials, or any combination thereof, and may be formed using, for example, PVD, CVD, ALD, other suitable techniques, or any combination thereof. In accordance with some embodiments, the second etch stop layer 122 may be of either a single-layer structure or a multilayer structure, and may have a thickness in a range from about 2 angstroms to about 200 angstroms. In accordance with some embodiments, the third dielectric layer 124 may be composed of, for example, Si, C, O, H, low-k materials, other suitable elements and/or materials, or any combination thereof, and may be formed using, for example, CVD, ALD, other suitable techniques, or any combination thereof. In accordance with some embodiments, the third dielectric layer 124 may have a thickness in a range from about 100 angstroms to about 2000 angstroms. In the following process, the third dielectric layer 124 may be formed with metal vias and metal trenches as well, and details thereof are omitted herein for the sake of brevity.

As a result, an interconnection structure is formed through steps S01 to S04. The interconnection structure includes the substrate 100 that is formed with the first metal via 104 and the first metal trench 106 therein, the first etch stop layer 108, the second dielectric layer 110, the second metal via 118 and the second metal trenches 120 that are formed in the second dielectric layer 110, and, optionally, one or more interconnection layers formed over the second dielectric layer 110 (e.g., the second etch stop layer 122, the third dielectric layer 124, and/or the metal vias and the metal trenches formed in the third dielectric layer 124), where the second metal via 118 interconnects the first metal trench 106 and one of the second metal trenches 120.

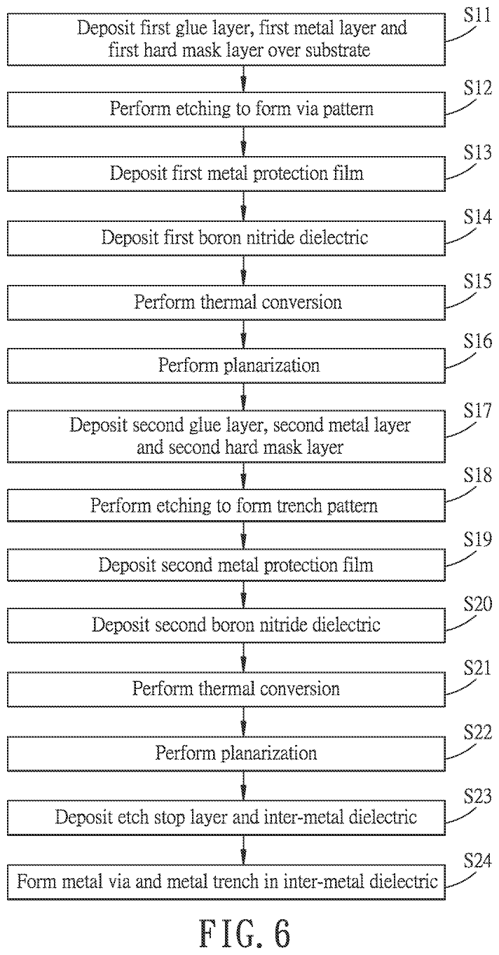

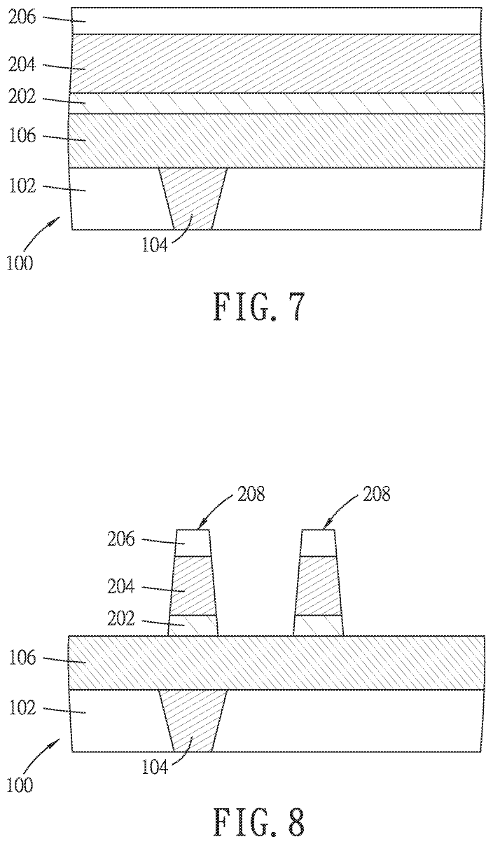

FIG. 6 is a flow chart that cooperates with FIGS. 7 through 20 to illustrate steps of a method for fabricating an interconnection structure in accordance with a second embodiment, where FIGS. 7 through 20 exemplarily depict a metal subtractive process. In FIG. 7, a substrate 100 is provided to include a first dielectric layer 102, a first metal via 104, and a first metal trench (or metal line) 106, which are exemplified to be the same as those in the first embodiment (see FIG. 2), and details thereof are not repeated herein for the sake of brevity.

Referring to FIGS. 6 and 7, a first glue layer 202, a first metal layer 204 and a first hard mask layer 206 are deposited over the substrate 100 in the given order (step S11). The first glue layer 202 may be composed of, for example, Ta, Ti, TaN, TiN, other suitable metals and/or their nitrides, other suitable materials, or any combination thereof, and may be formed using, for example, PVD, CVD, ALD, other suitable techniques, or any combination thereof. In accordance with some embodiments, the first glue layer 202 is used to provide good adhesion to the first metal layer 204, and may have a thickness in a range from about 2 angstroms to about 100 angstroms. The first metal layer 204 may include, for example, Cu, Co, Ru, Mo, Cr, W, Mn, Rh, Ir, Ni, Pd, Pt, Ag, Au, Al, alloys of these metal elements, other suitable materials, or any combination thereof, and may be formed using, for example, PVD, CVD, ALD, other suitable techniques, or any combination thereof. In accordance with some embodiments, the first metal layer 204 may have a thickness in a range from about 50 angstroms to about 500 angstroms. In accordance with some embodiments, the first hard mask layer 206 may be of either a single-layer structure or a multilayer structure, where each layer may be composed of, for example, Si, W, Ti, Be, Hf, Zr, O, N, C, other suitable elements, or any combination thereof, and may be formed using, for example, CVD, ALD, spin-on deposition, other suitable techniques, or any combination thereof. In accordance with some embodiments, the first hard mask layer 206 may have a thickness in a range from about 100 angstroms to about 500 angstroms.

Referring to FIGS. 6 and 8, the first hard mask layer 206, the first metal layer 204 and the first glue layer 202 are etched to form a via pattern (step S12), and the first metal trench 106 is revealed (noting that the first dielectric layer 102 may be revealed as well, but is not shown from the perspective of FIG. 8), where the first hard mask layer 206 serves as an etching mask during the etching of the first metal layer 204 and the first glue layer 202. In the illustrative embodiment, the via pattern exemplarily includes multiple via features 208 each including multiple portions respectively of the first glue layer 202, the first metal layer 204 and the first hard mask layer 206 that are stacked in the given order from bottom to top. In accordance with some embodiments, the first hard mask layer 206 may be patterned using a lithography process, and may be etched using, for example, wet etching, dry etching, other suitable techniques, or any combination thereof. In accordance with some embodiments, the first metal layer 204 and the first glue layer 202 may be etched using, for example, isotropic etching, anisotropic etching, other suitable techniques, or any combination thereof, with the patterned first hard mask layer 206 serving as an etching mask. For example, etching techniques such as RIE, IBE, atomic layer etching (ALE), etc., may be used in step S12. Each of the via features 208 may have a width that gradually increases from top to bottom due to the nature of etching, and thus may have a bottom width that is greater than its top width. In accordance with some embodiments, a wet chemical cleaning process may be performed after dry etching of the first metal layer 204 and the first glue layer 202, in order to reduce polymers induced by the dry etching.

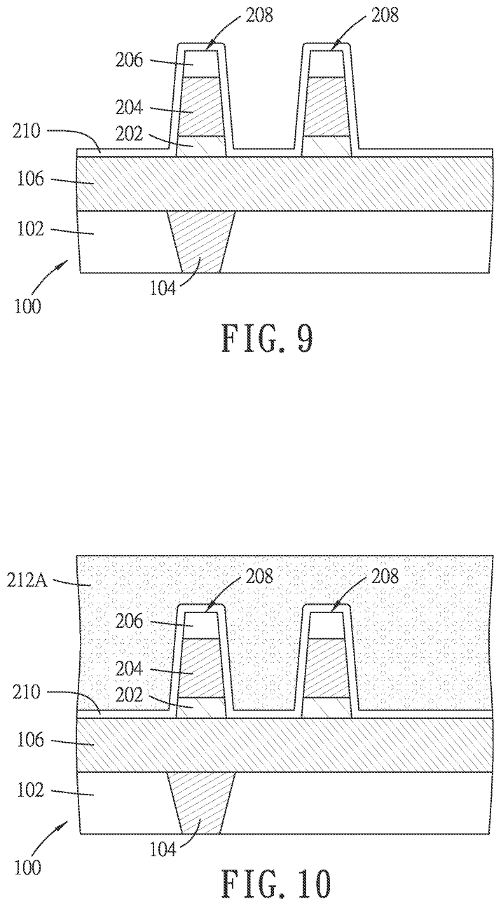

Referring to FIGS. 6 and 9, a first metal protection film 210 is conformally deposited over the first metal trench 106, the first dielectric layer 102 and the via features 208 (step S13), so that the first metal protection film 210 covers and surrounds the via features 208. In accordance with some embodiments, the first metal protection film 210 has a low thermal conductivity that is smaller than 1 W/(m· K), and has good adhesion to the first dielectric layer 102, the first glue layer 202, the first metal layer 204 and the first hard mask layer 206. In accordance with some embodiments, the first metal protection film 210 may include, for example, SiO, SiOC, SiCN, SiN, AlN, AlO, other suitable materials, or any combination thereof, and may be formed using, for example, PVD, CVD, ALD, plasma-enhanced CVD (PECVD), plasma-enhanced ALD (PEALD), other suitable techniques, or any combination thereof. In accordance with some embodiments, the first metal protection film 210 may have a thickness in a range from about 2 angstroms to about 50 angstroms. In different crystalline states, the material(s) used in the first metal protection film 210 may have different thermal conductivities. In this embodiment, for the purpose of making the first metal protection film 210 have a small thermal conductivity, the relevant deposition process may be controlled in terms of temperature and pressure to cause the material(s) to be formed in an amorphous state.

Referring to FIGS. 6 and 10, a first boron nitride dielectric 212A is deposited over the first metal protection film 210 (step S14) using, for example, CVD, ALD, spin-on deposition, other suitable techniques, or any combination thereof, so that a gap between the via features 208 is filled up, and the via features 208 are surrounded by the first boron nitride dielectric 212A. In accordance with some embodiments, tris(dimethylamino) borane (TDMAB) may be used with NH₃ to form the first boron nitride dielectric 212A with good gap-filling performance, where the first boron nitride dielectric 212A is made of amorphous boron nitride that has a desired low dielectric constant as well as a desired good mechanical strength, but this disclosure is not limited to any specific method of forming the boron nitride. In accordance with some embodiments, the first boron nitride dielectric 212A has good adhesion to the first metal protection film 210, and may have a thickness in a range from about 10 angstroms to about 700 angstroms.

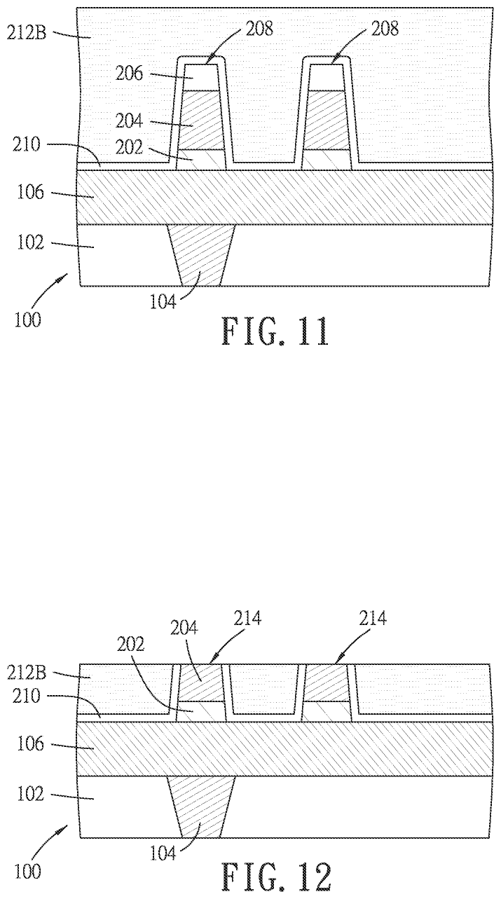

Referring to FIGS. 6 and 11, a thermal conversion process is performed (step S15) on the first boron nitride dielectric 212A using, for example, ultraviolet, a furnace, laser annealing, rapid thermal annealing, other suitable techniques, or any combination thereof, and thus the first boron nitride dielectric 212A turns into a processed first boron nitride dielectric 212B that is still in the amorphous state and that has better film properties in terms of dielectric constant and mechanical strength. The thermal conversion is used to remove or reduce carbon elements, which may come from precursors that are used in step S14, from the first boron nitride dielectric 212A, so as to enhance crosslinks among boron nitride molecules, thereby achieving a lower effective dielectric constant and a better mechanical strength. In accordance with some embodiments, the thermal conversion process may be performed with a process temperature in a range from about 350° C. to about 750° C. In a case where the thermal conversion process is performed using ultraviolet or a furnace, a duration of the thermal conversion process may be less than about ten minutes. In a case where the thermal conversion process is performed using laser annealing or rapid thermal annealing, a duration of the thermal conversion process may be less than about five seconds. Because of the low thermal conductivity, the first metal protection film 210 can isolate the via features 208 from heat during the thermal conversion process, thereby preventing the metal elements in the via features 208 from diffusing into the boron nitride during the thermal conversion process.

Referring to FIGS. 6 and 12, a planarization process is performed (step S16) to remove the first hard mask layer 206 (see FIG. 11) and reveal the first metal layer 204, so as to turn the via features 208 into second metal vias 214 that are surrounded by the processed first boron nitride dielectric 212B. The planarization process may include, for example, a CMP process, other suitable processes, or any combination thereof. In accordance with some embodiments, the resultant second metal vias 214 may have a thickness in a range from about 50 angstroms to about 300 angstroms.

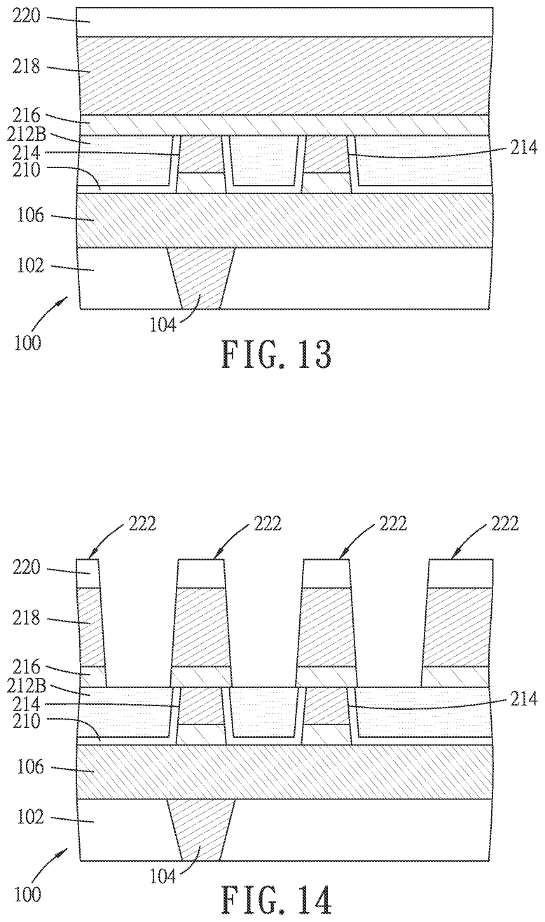

Referring to FIGS. 6 and 13, a second glue layer 216, a second metal layer 218 and a second hard mask layer 220 are deposited (step S17) in the given order over the second metal vias 214 and the processed first boron nitride dielectric 212B. The second glue layer 216 may be composed of, for example, Ta, Ti, TaN, TiN, other suitable metals and/or their nitrides, other suitable materials, or any combination thereof, and may be formed using, for example, PVD, CVD, ALD, other suitable techniques, or any combination thereof. In accordance with some embodiments, the second glue layer 216 is used to provide good adhesion to the second metal layer 218, and may have a thickness in a range from about 2 angstroms to about 100 angstroms. The second metal layer 218 may include, for example, Cu, Co, Ru, Mo, Cr, W, Mn, Rh, Ir, Ni, Pd, Pt, Ag, Au, Al, alloys of these metal elements, other suitable materials, or any combination thereof, and may be formed using, for example, PVD, CVD, ALD, other suitable techniques, or any combination thereof. In accordance with some embodiments, the second metal layer 218 may have a thickness in a range from about 50 angstroms to about 500 angstroms. In accordance with some embodiments, the second hard mask layer 220 may be of either a single-layer structure or a multilayer structure, where each layer may be composed of, for example, Si, W, Ti, Be, Hf, Zr, O, N, C, other suitable elements, or any combination thereof, and may be formed using, for example, CVD, ALD, spin-on deposition, other suitable techniques, or any combination thereof. In accordance with some embodiments, the second hard mask layer 220 may have a thickness in a range from about 100 angstroms to about 500 angstroms.

Referring to FIGS. 6 and 14, the second hard mask layer 220, the second metal layer 218 and the second glue layer 216 are etched to form a trench pattern (step S18), and the processed first boron nitride dielectric 212B is revealed, where the second hard mask layer 220 serves as an etching mask during the etching of the second metal layer 218 and the second glue layer 216. In the illustrative embodiment, the trench pattern exemplarily includes multiple trench features 222 each including multiple portions respectively of the second glue layer 216, the second metal layer 218 and the second hard mask layer 220 that are stacked in the given order from bottom to top; and some of the trench features 222 are stacked over the second metal vias 214. In accordance with some embodiments, the second hard mask layer 220 may be patterned using a lithography process, and may be etched using, for example, wet etching, dry etching, other suitable techniques, or any combination thereof. In accordance with some embodiments, the second metal layer 218 and the second glue layer 216 may be etched using, for example, isotropic etching, anisotropic etching, other suitable techniques, or any combination thereof, with the patterned second hard mask layer 220 serving as an etching mask. For example, etching techniques such as RIE, IBE, ALE, etc., may be used in step S18. Each of the trench features 222 may have a width that gradually increases from top to bottom due to the nature of etching, and thus may have a bottom width that is greater than its top width. In accordance with some embodiments, a wet chemical cleaning process may be performed after dry etching of the second metal layer 218 and the second glue layer 216, in order to reduce polymers induced by the dry etching.

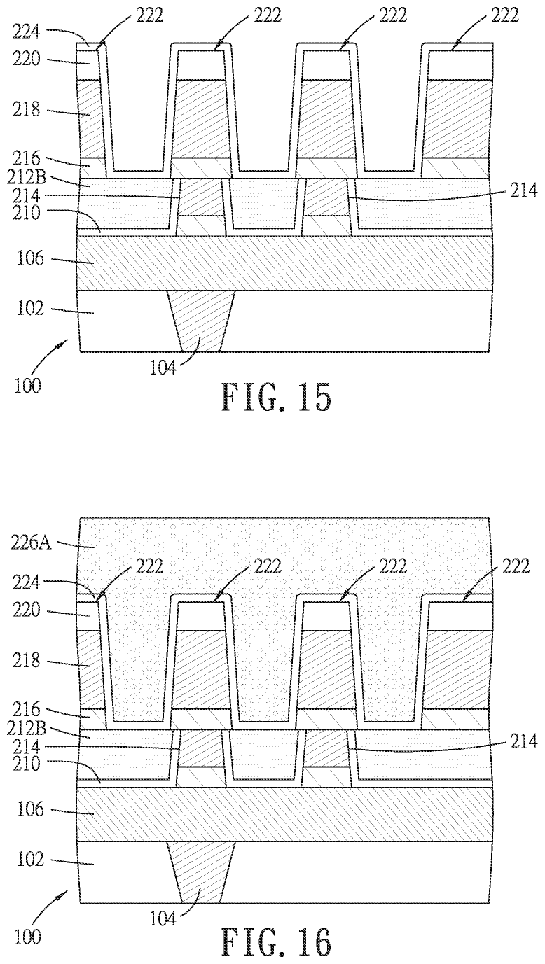

Referring to FIGS. 6 and 15, a second metal protection film 224 is conformally deposited over the processed first boron nitride dielectric 212B and the trench features 222 (step S19), so that the second metal protection film 224 covers and surrounds the trench features 222. In accordance with some embodiments, the second metal protection film 224 has a low thermal conductivity that is smaller than 1 W/(m·K), and has good adhesion to boron nitride, the second glue layer 216, the second metal layer 218 and the second hard mask layer 220. In accordance with some embodiments, the second metal protection film 224 may include, for example, SiO, SiOC, SiCN, SiN, AlN, AlO, other suitable materials, or any combination thereof, and may be formed using, for example, PVD, CVD, ALD, PECVD, PEALD, other suitable techniques, or any combination thereof. In accordance with some embodiments, the second metal protection film 224 may have a thickness in a range from about 2 angstroms to about 50 angstroms. In different crystalline states, the material(s) used in the second metal protection film 224 may have different thermal conductivities. In this embodiment, for the purpose of making the second metal protection film 224 have a small thermal conductivity, the relevant deposition process may be controlled in terms of temperature and pressure to cause the material(s) to be formed in an amorphous state.

Referring to FIGS. 6 and 16, a second boron nitride dielectric 226A is deposited over the second metal protection film 224 (step S20) using, for example, CVD, ALD, spin-on deposition, other suitable techniques, or any combination thereof, so that gaps among the trench features 222 are filled up, and the trench features 222 are surrounded by the second boron nitride dielectric 226A. In accordance with some embodiments, TDMAB may be used with NH₃ to form the second boron nitride dielectric 226A with good gap-filling performance, where the second boron nitride dielectric 226A is made of amorphous boron nitride that has a desired low dielectric constant as well as a desired good mechanical strength, but this disclosure is not limited to any specific method of forming the boron nitride. In accordance with some embodiments, the second boron nitride dielectric 226A has good adhesion to the second metal protection film 224, and may have a thickness in a range from about 10 angstroms to about 700 angstroms.

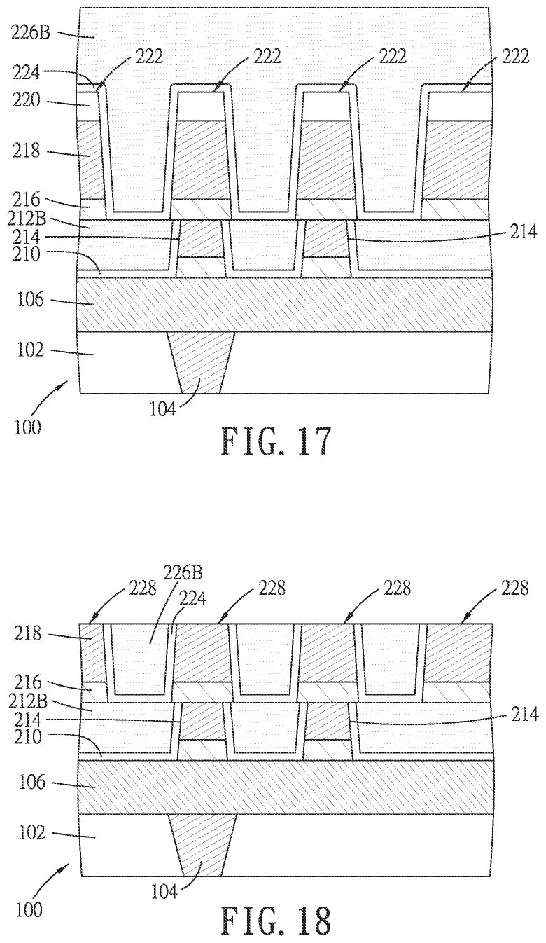

Referring to FIGS. 6 and 17, a thermal conversion process is performed (step S21) on the second boron nitride dielectric 226A using, for example, ultraviolet, a furnace, laser annealing, rapid thermal annealing, other suitable techniques, or any combination thereof, such that the second boron nitride dielectric 226A turns into a processed second boron nitride dielectric 226B that is still in the amorphous state and that has better film properties in terms of dielectric constant and mechanical strength. The thermal conversion is used to remove or reduce carbon elements, which may come from precursors that are used in step S20, from the second boron nitride dielectric 226A, so as to enhance crosslinks among boron nitride molecules, thereby achieving a lower effective dielectric constant and a better mechanical strength. In accordance with some embodiments, the thermal conversion process may be performed with a process temperature in a range from about 350° C. to about 750° C. In a case where the thermal conversion process is performed using ultraviolet or a furnace, a duration of the thermal conversion process may be less than about ten minutes. In a case where the thermal conversion process is performed using laser annealing or rapid thermal annealing, a duration of the thermal conversion process may be less than about five seconds. Because of the low thermal conductivity, the second metal protection film 224 can isolate the trench features 222 from heat during the thermal conversion process, thereby preventing the metal elements in the trench features 222 from diffusing into boron nitride during the thermal conversion process.

Referring to FIGS. 6 and 18, a planarization process is performed (step S22) to remove the second hard mask layer 220 (see FIG. 17) and reveal the second metal layer 218, so as to turn the trench features 222 into second metal trenches 228 that are surrounded by the processed second boron nitride dielectric 226B. The planarization process may include, for example, a CMP process, other suitable processes, or any combination thereof. In accordance with some embodiments, the resultant second metal trenches 228 may have a thickness in a range from about 50 angstroms to about 300 angstroms.

As a result, an interconnection structure is formed through steps S11 to S22. The interconnection structure includes the substrate 100 that is formed with the first metal via 104 and the first metal trench 106 therein, the processed first boron nitride dielectric 212B formed over the substrate 100, the processed second boron nitride dielectric 226B formed over the processed first boron nitride dielectric 212B, the second metal vias 214 formed in the processed first boron nitride dielectric 212B, and the second metal trenches 228 formed in the processed second boron nitride dielectric 226B, where the second metal vias 214 connect some of the second metal trenches 228 to the first metal trench 106. In accordance with some embodiments, the processed first boron nitride dielectric 212B and the processed second boron nitride dielectric 226B may include hydrogen elements attached to the structure of boron nitride, where the hydrogen elements may come from precursors and reaction gases that are used for forming the boron nitride. The interconnection structure further includes the first metal protection film 210 and the second metal protection film 224, where the first metal protection film 210 is disposed between the second metal vias 214 and the processed first boron nitride dielectric 212B and between the substrate 100 and the processed first boron nitride dielectric 212B, and the second metal protection film 224 is disposed between the second metal trenches 228 and the processed second boron nitride dielectric 226B and between the processed first boron nitride dielectric 212B and the processed second boron nitride dielectric 226B. The first metal protection film 210 surrounds the second metal vias 214 and separates the second metal vias 214 from the processed first boron nitride dielectric 212B. The second metal protection film 224 surrounds the second metal trenches 228 and separates the second metal trenches 228 from the processed second boron nitride dielectric 226B. Each of the second metal vias 214 and the second metal trenches 228 may have a width that gradually increases from top to bottom because of the nature of the metal subtractive process, and thus may have a bottom width that is greater than its top width. By virtue of the metal subtractive process (i.e., patterning metal prior to depositing dielectric for gap filling), the boron nitride dielectrics 212B, 226B are not etched, so the second embodiment may be advantageous in that no etching damages would be generated in the boron nitride dielectrics 212B, 226B when compared to the first embodiment, where, as shown in FIG. 3, the etching of the second dielectric layer 110 and/or the following cleaning process may cause damages (denoted by symbols “x” on sidewalls of the via hole 114 and the trench recesses 116) to the second dielectric layer 110, which may lead to increase of effective dielectric constant (namely, the k value) of the second dielectric layer 110, and thus worsen circuit properties in terms of capacitance. Furthermore, in comparison to the dielectric material(s) used in the first embodiment, the boron nitride that is used as interlayer dielectric in the second embodiment has, in addition to its small dielectric constant, a higher Young's modulus that provides better stiffness, so as to fulfill the requirements in terms of film property (e.g., small dielectric constant) and good mechanical strength for package at the same time. In accordance with some embodiments, the second metal vias 214 and the second metal trenches 228 may be formed using different fabrication processes. For example, the second metal vias 214 may be formed using a damascene process, while the second metal trenches 228 are formed using the metal subtractive process because distribution of metal trenches is usually denser than distribution of metal vias, and thus the damages to the dielectric would have greater influence on the layer of metal trenches in terms of capacitance.

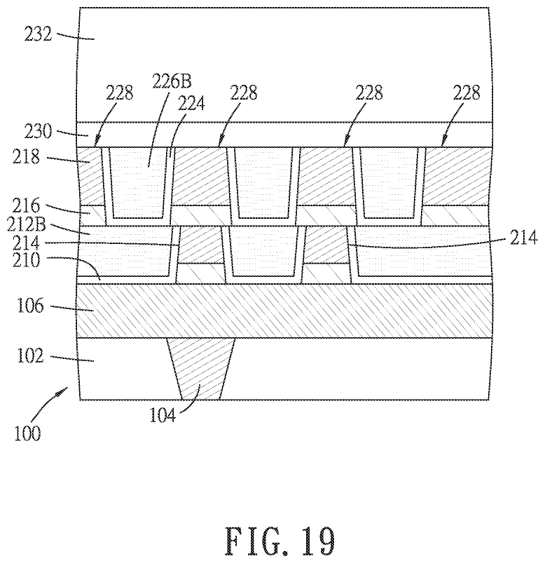

Referring to FIGS. 6 and 19, an etch stop layer 230 and a second dielectric layer 232 are deposited in the given order over the processed second boron nitride dielectric 226B and the second metal trenches 228 (step S23). Before the deposition of the etch stop layer 230, a pretreatment process may be applied in order to remove metal oxide that may have been formed on top of the second metal trenches 228 during a time gap between the formation of the second metal trenches 228 and the deposition of the etch stop layer 230, and the pretreatment process may use, for example, NH₃ plasma, H₂ plasma, other suitable treatments, or any combination thereof. In accordance with some embodiments, the etch stop layer 230 may have a thickness in a range from about 2 angstroms to about 200 angstroms. In accordance with some embodiments, the second dielectric layer 232 may have a thickness in a range from about 100 angstroms to about 2000 angstroms. In the illustrative embodiment, materials and formation of the etch stop layer 230 and the second dielectric layer 232 may be similar to the materials and the formation of the second etch stop layer 122 and the third dielectric layer 124 of the first embodiment (see FIG. 5), so details thereof are not repeated herein for the sake of brevity.

The second embodiment is advantageous in that the second boron nitride dielectric 226B is scarcely damaged by the pretreatment process that usually uses the H₂ plasma or the NH₃ plasma when compared to the first embodiment, where the pretreatment process may cause damages (denoted by symbols “x” on top of the second dielectric layer 110 in FIG. 5) to the second dielectric layer 110, leading to carbon loss in the second dielectric layer 110, and the effective dielectric constant of the second dielectric layer 110 may thus increase. Conventional low-k dielectrics are SiOCH-based, and carbon elements play an important role in achieving the low dielectric constant, so element mapping can be used to observe whether a low-k dielectric has carbon loss on its surface relative to its bulk, so as to determine whether the low-k dielectric is damaged. However, the boron nitride, which is used as a low-k dielectric in the second embodiment, does not include carbon elements, and formation thereof involves the use of NH₃, so the pretreatment process would hardly damage the boron nitride.

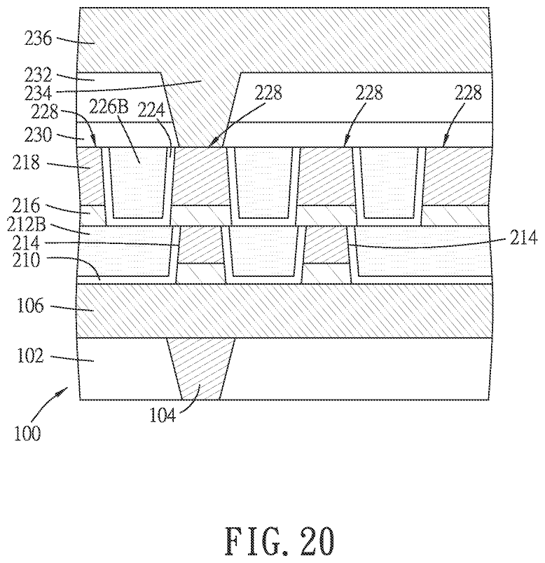

Referring to FIGS. 6 and 20, a third metal via 234 and a third metal trench 236 are formed in the second dielectric layer 232 (step S24) using, for example, a dual damascene process, where the third metal via 234 penetrates the etch stop layer 230 and interconnects the third metal trench 236 and one of the second metal trenches 228. It is noted that the formation of the third metal via 234 and the third metal trench 236 is not limited to any specific process. For instance, the third metal via 234 or the third metal trench 236 or both may also be formed using the metal subtractive process as introduced in steps S11 through S22 as shown in FIG. 6.

In accordance with some embodiments, an interconnection structure is provided to include a substrate that is formed with a first metal trench, a boron nitride dielectric that is disposed over the substrate, a second metal trench that is formed in the boron nitride dielectric, and a metal via that is disposed to interconnect the first metal trench and the second metal trench.

In accordance with some embodiments, a bottom width of the second metal trench is greater than a top width of the second metal trench, and a bottom width of the metal via is greater than a top width of the metal via.

In accordance with some embodiments, the interconnection structure further includes a first metal protection film that is disposed between the second metal trench and the boron nitride dielectric, and that has a thermal conductivity smaller than 1 W/(m·K).

In accordance with some embodiments, the interconnection structure further includes another dielectric disposed between the substrate and the boron nitride dielectric, wherein the metal via is formed in the another dielectric, and the first metal protection film is further disposed between the boron nitride dielectric and the another dielectric.

In accordance with some embodiments, the another dielectric includes boron nitride.

In accordance with some embodiments, the interconnection structure further includes a second metal protection film disposed between the metal via and the another dielectric, and the second metal protection film has a thermal conductivity smaller than 1 W/(m·K).

In accordance with some embodiments, the first metal protection film is further disposed between the another dielectric and the substrate.

In accordance with some embodiments, an interconnection structure is provided to include a substrate that is formed with a first metal trench, a first dielectric that is disposed over the substrate, a metal via that is disposed in the first dielectric and that is connected to the first metal trench, a second dielectric that is disposed over the first dielectric and that includes boron nitride, and a second metal trench that is disposed in the second dielectric and that is connected to the metal via.

In accordance with some embodiments, a bottom width of the second metal trench is greater than a top width of the second metal trench, and a bottom width of the metal via is greater than a top width of the metal via.

In accordance with some embodiments, the interconnection structure further includes a first metal protection film that surrounds the second metal trench and that separates the second metal trench from the second dielectric, wherein the first metal protection film has a thermal conductivity smaller than 1 W/(m·K).

In accordance with some embodiments, the first metal protection film is disposed over the first dielectric and under the second dielectric.

In accordance with some embodiments, the first dielectric includes boron nitride.

In accordance with some embodiments, the interconnection structure further includes a second metal protection film that surrounds the metal via and that separates the metal via from the first dielectric, wherein the second metal protection film has a thermal conductivity smaller than 1 W/(m·K).

In accordance with some embodiments, the second metal protection film is disposed over the substrate and under the first dielectric.

In accordance with some embodiments, a method for fabricating an interconnection structure is provided. In one step, a metal via is formed over a first metal trench that is formed in a substrate. In one step, a trench feature is formed over the metal via. In one step, a first dielectric is formed to include boron nitride and to surround the trench feature.

In accordance with some embodiments, the method further includes, between the step of forming the trench feature and the step of forming the first dielectric, a step of conformally forming a first metal protection film over the trench feature. The first dielectric is formed over the first metal protection film. The method further includes, after the step of forming the first dielectric, a step of performing thermal conversion on the first dielectric.

In accordance with some embodiments, the first metal protection film has a thermal conductivity smaller than 1 W/(m·K).

In accordance with some embodiments, the step of forming the metal via includes a sub-step of forming a via feature over the first metal trench, and a sub-step of forming a second dielectric that includes boron nitride and that surrounds the via feature.

In accordance with some embodiments, the step of forming the metal via further includes, between the sub-step of forming the via feature and the sub-step of forming the second dielectric, a sub-step of conformally forming a second metal protection film over the via feature. The second dielectric is formed over the second metal protection film. The step of forming the metal via further includes, after the sub-step of forming the second dielectric, a sub-step of performing thermal conversion on the second dielectric.

In accordance with some embodiments, the second metal protection film has a thermal conductivity smaller than 1 W/(m·K).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure, comprising:
a substrate that is formed with a first metal trench;
a boron nitride dielectric that is disposed over the substrate;
a second metal trench that is formed in the boron nitride dielectric; and
a metal via that is disposed to interconnect the first metal trench and the second metal trench.

2. The interconnection structure according to claim 1, wherein:
a bottom width of the second metal trench is greater than a top width of the second metal trench; and
a bottom width of the metal via is greater than a top width of the metal via.

3. The interconnection structure according to claim 1, further comprising a first metal protection film that is disposed between the second metal trench and the boron nitride dielectric, and that has a thermal conductivity smaller than 1 W/(m·K).

4. The interconnection structure according to claim 3, further comprising another dielectric disposed between the substrate and the boron nitride dielectric, wherein the metal via is formed in the another dielectric, and the first metal protection film is further disposed between the boron nitride dielectric and the another dielectric.

5. The interconnection structure according to claim 4, wherein the another dielectric includes boron nitride.

6. The interconnection structure according to claim 5, further comprising a second metal protection film disposed between the metal via and the another dielectric, and the second metal protection film has a thermal conductivity smaller than 1 W/(m·K).

7. The interconnection structure according to claim 6, wherein the first metal protection film is further disposed between the another dielectric and the substrate.

8. An interconnection structure, comprising:
a substrate that is formed with a first metal trench;
a first dielectric that is disposed over the substrate;
a metal via that is disposed in the first dielectric and that is connected to the first metal trench;
a second dielectric that is disposed over the first dielectric and that includes boron nitride; and
a second metal trench that is disposed in the second dielectric and that is connected to the metal via.

9. The interconnection structure according to claim 8, wherein a bottom width of the second metal trench is greater than a top width of the second metal trench; and
a bottom width of the metal via is greater than a top width of the metal via.

10. The interconnection structure according to claim 8, further comprising a first metal protection film that surrounds the second metal trench and that separates the second metal trench from the second dielectric, wherein the first metal protection film has a thermal conductivity smaller than 1 W/(m·K).

11. The interconnection structure according to claim 10, wherein the first metal protection film is disposed over the first dielectric and under the second dielectric.

12. The interconnection structure according to claim 11, wherein the first dielectric includes boron nitride.

13. The interconnection structure according to claim 12, further comprising a second metal protection film that surrounds the metal via and that separates the metal via from the first dielectric, wherein the second metal protection film has a thermal conductivity smaller than 1 W/(m·K).

14. The interconnection structure according to claim 13, wherein the second metal protection film is disposed over the substrate and under the first dielectric.

15. A method for fabricating an interconnection structure, comprising steps of:
forming a metal via over a first metal trench that is formed in a substrate;
forming a trench feature over the metal via; and
forming a first dielectric that includes boron nitride and that surrounds the trench feature.

16. The method according to claim 15, further comprising, between the step of forming the trench feature and the step of forming the first dielectric, a step of conformally forming a first metal protection film over the trench feature,
wherein the first dielectric is formed over the first metal protection film;
the method further comprising, after the step of forming the first dielectric, a step of performing thermal conversion on the first dielectric.

17. The method according to claim 16, wherein the first metal protection film has a thermal conductivity smaller than 1 W/(m·K).

18. The method according to claim 16, wherein the step of forming the metal via includes sub-steps of:
forming a via feature over the first metal trench; and
forming a second dielectric that includes boron nitride and that surrounds the via feature.

19. The method according to claim 18, wherein the step of forming the metal via further includes, between the sub-step of forming the via feature and the sub-step of forming the second dielectric, a sub-step of conformally forming a second metal protection film over the via feature,
wherein the second dielectric is formed over the second metal protection film; and
wherein the step of forming the metal via further includes, after the sub-step of forming the second dielectric, a sub-step of performing thermal conversion on the second dielectric.

20. The method according to claim 19, wherein the second metal protection film has a thermal conductivity smaller than 1 W/(m·K).
